(19) United States
(12) Patent Application Publication
(10) Pub. No.: US 2005/0202617 A1
(43) Pub. Date: Sep. 15, 2005

(54) Gate structure for a transistor and method for fabricating the gate structure

(76) Inventors: Jens Hahn, Dresden (DE); Sven Schmidbauer, Dresden (DE); Axel Buerke, Dresden (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/044,730

(22) Filed: Jan. 28, 2005

(30) Foreign Application Priority Data
Jan. 30, 2004 (DE) 10 2004 004 864.9

(51) Int. Cl. H01L 21/8234

(52) U.S. Cl. 438/197

(57) ABSTRACT

A gate structure includes a gate electrode layer stack with a doped polysilicon layer and a gate metal layer. Between the doped polysilicon layer and the gate metal layer is a barrier layer made of metal nitride for suppressing a chemical reaction between metal and silicon. A contact layer made of metal and covering the polysilicon layer is provided on the polysilicon layer to prevent nitriding of the polysilicon layer and to reduce contact resistance. The contact layer includes titanium and the barrier layer includes titanium nitride. Since titanium nitride is chemically and thermally stable, the nitrogen remains fixedly bound in the barrier layer, which reduces the probability of a nitriding of the polysilicon layer.

### CROSS REFERENCE TO RELATED APPLICATIONS

This application claims priority under 35 USC § 119 to German Application No. DE 10 2004 004 864.9, filed on Jan. 30, 2004, and titled “Gate Structure for a Transistor and Method for Fabricating the Gate Structure,” the entire contents of which are hereby incorporated by reference.

### BACKGROUND

Transistors form a central component of integrated circuits and are included, for example, in Flash or DRAM (Dynamic Random Access Memory) chips. DRAM memory chips have a transistor and at least one storage capacitor in each memory cell. Gate electrodes of the transistors of memory chips are usually an integral component of a word line that connects a plurality of transistors to one another. A gate structure forming the gate electrode generally includes a patterned gate electrode layer stack having a doped polysilicon layer, which is provided on a gate dielectric layer, and a gate metal layer. The gate metal layer is a component of the word line and comprises a metal or metal compounds.

A known gate structure has a polysilicon layer and an overlying tungsten silicide layer. The tungsten silicide layer forms the gate metal layer. The requirements of the gate metal layer are a low bulk resistance in the longitudinal direction and a low contact resistance with respect to the underlying polysilicon layer.

FIG. 1A illustrates a conventional gate structure 1. The gate structure 1 has a gate electrode layer stack 2. The sidewalls of the gate electrode layer stack 2 are surrounded with an insulating layer 3. The gate electrode layer stack 2 is in contact with a gate dielectric layer 9 arranged on a semiconductor substrate 10 in which the transistor is formed. In this example, the gate electrode layer stack 2 includes a doped polysilicon layer 5 on which a tungsten silicide layer 81 is provided. The gate metal layer is formed by the tungsten silicide layer 81. The tungsten silicide layer 81 is covered with an insulating cap 4. The sidewall oxide 32 is situated on the sidewalls of the polysilicon layer 5. On the sidewall oxide 32, there is an insulating spacer nitride layer 31 or spacer oxide layer, which envelopes the sidewalls of the electrode layer stack 2 and the insulating cap 4.

Compared to a metal layer, a metal silicide layer has a higher resistivity. Since the resistance of the word line should be as low as possible in order to enable a short RC delay and thus a fast memory access to the information contained in the memory cells, the cross-sectional area of the metal silicide layer is not permitted to become arbitrarily small. For this reason, limits are imposed on reducing the height of the electrode layer stack. Reducing the height of the electrode layer stack is desirable for process engineering reasons since the planarity of the integrated circuit can be improved, which, in turn, improves the quality of the photolithographic processes used. Moreover, a high electrode layer stack adversely affects an oblique implantation of source/drain regions of the transistor.

Since the operating speed of a circuit also depends on the conductivity of the word lines and the gate electrode that in part form the word lines, materials having a low resistivity are used. The bulk resistance is reduced if the metal silicide layer is replaced by a metal layer.

A further conventional gate structure 1 with a gate metal layer 8 made of a metal, for example, tungsten, is illustrated in FIG. 1B. The gate structure 1 differs from the gate structure 1 illustrated in FIG. 1A by the relatively smaller layer thicknesses of the polysilicon layer 5 and the gate metal layer 8. Also, the barrier layer 7, which is provided on the polysilicon layer 5, includes a tungsten nitride. As can be seen from FIG. 1B, the height of the gate electrode layer stack 2 is significantly reduced compared to the gate electrode layer stack 2 of FIG. 1A since the gate metal layer made of tungsten, given the same bulk resistance, can be predefined with a smaller layer thickness than the metal silicide.

The tungsten of the gate metal layer is not applied directly to the polysilicon layer since tungsten silicide would otherwise arise at an interface between the gate metal layer and the polysilicon layer during subsequent high-temperature steps. The tungsten silicide at the interface increases the contact resistance between the gate metal layer, and the polysilicon layer, and possibly leads to the detachment of the gate electrode layer stack. However, the lower the contact resistance, the shorter possible switching times. Therefore, the barrier layer of tungsten nitride is provided between the gate metal layer and the polysilicon layer. The tungsten nitride prevents interaction between tungsten and silicon.

An essential disadvantage in a conventional barrier layer of tungsten nitride, is that the nitrogen is not sufficiently bound to the tungsten nitride, so that the nitrogen diffuses, for example, several nanometers into the underlying polysilicon, for example, after later thermal steps. As a result, silicon nitride is formed, which increases contact resistance.

FIGS. 2A and 2B illustrate two measurement curves a and b, respectively, illustrating the occurrence of tungsten and the occurrence of nitrogen as a function of the position in the gate electrode layer stack. In each case, the distance from an upper edge of the gate electrode layer stack in nanometers is plotted on the abscissa and the number of counting events for tungsten and nitrogen, respectively, is plotted on the ordinate. The tungsten layer is situated in section 8 on the abscissa. The barrier layer of tungsten nitride is situated in section 7 and the polysilicon layer, in section 5. The two measurement curves were recorded after a thermal step of approximately 800° C. As seen from curve a, tungsten diffused into the polysilicon to a relatively small extent. Curve b, by contrast, shows a relatively significant nitrogen component in the polysilicon.

The electron microscope micrograph in FIG. 3 shows a longitudinal section through the gate electrode layer stack, on which the measurement curves in FIGS. 2A and 2B are also based. The thin barrier layer 7 of tungsten nitride contacts the polysilicon layer 5 and the gate metal layer 8 of tungsten contacts the thin barrier layer 7. Nitrogen diffuses into the polysilicon layer to a depth of several nanometers and forms insulating silicon nitride there.

### SUMMARY

A method for fabricating a gate structure with a low contact resistance and a gate structure of a transistor as compared to conventional gate structures is desirable.

To form the gate electrode layer stack, a polysilicon layer is applied on a gate dielectric layer provided on the semiconductor substrate. A barrier layer of a metal nitride and a gate metal layer are provided. The barrier layer prevents an interaction, which increases contact resistance between the polysilicon layer and the gate metal layer, between the silicon in the polysilicon layer and the metal of the gate metal layer. A contact layer for preventing an interaction between the nitrogen in the barrier layer and the silicon in the polysilicon layer is provided between the polysilicon layer and the barrier layer.

Nitriding of the polysilicon layer is caused by diffusion of nitrogen from the barrier layer. If the barrier layer includes a metal nitride deposited directly onto the polysilicon, for instance, in the course of a Physical Vapor Deposition (PVD) method, then nitriding of the surface of the polysilicon layer occurs in the nitrogen-containing process atmosphere during the PVD deposition. Formation of a silicon nitride layer that disadvantageously increases the contact resistance of the gate metal layer with respect to the polysilicon layer occurs as a result of deposition of the nitrogen-containing barrier layer and of a thermal step in the subsequent processing.

According to the invention, therefore, the contact layer made of metal is applied onto the polysilicon layer successively with exclusion of nitrogen and the barrier layer is applied to the contact layer. Because the polysilicon layer is completely covered with a metal in a first step, an interaction between the nitrogen in the process atmosphere during application of the barrier layer, for example, by a PVD method, and the silicon in the polysilicon layer is avoided. The contact layer additionally acts as diffusion barrier that prevents a diffusion of nitrogen, for example, after a thermal step, to the polysilicon layer. The application of the contact layer according to the invention prevents silicon nitride from arising at an interface between the polysilicon layer and the barrier layer. Avoiding silicon nitride at the interface leads to a relatively significant reduction of the contact resistance between the polysilicon layer and the gate metal layer, compared to conventionally processed gate structures. As a result of a reduction of the contact resistance, switching times are shortened and faster access times to data contents are possible in a memory cell, for example.

The barrier layer is, for example, provided on the contact layer as a chemically, thermally, and mechanically stable layer. The nitrogen in the barrier layer remains fixedly bound, for example, at high temperatures used later in the process in order to prevent diffusion of nitrogen and to avoid interactions that adversely influence the contact resistance.

Refractory metal titanium is the material for the contact layer and titanium nitride is the material for the barrier layer. The use of titanium nitride for the barrier layer ensures that no nitrogen enters into the polysilicon because the nitrogen in the titanium nitride remains in the bound state, even at temperatures of more than 1000° C. For example, contact resistance between the gate metal layer and the polysilicon layer of less than 10 ohm square micrometer can be formed with the layer sequence titanium/titanium nitride. Compared to a conventional gate structure provided with tungsten nitride as barrier layer and with a contact resistance of greater than 10,000 ohm square micrometer, a relatively significant reduction of the contact resistance is obtained by the layer sequence titanium/titanium nitride according to the invention.

The contact layer has, for instance, a thickness in the range of 1 to 5 nm.

Tungsten is, for example, the material for the gate metal layer.

The gate metal layer may, for example, also be a layer sequence including tungsten nitride and tungsten.

The contact layer is applied to the polysilicon layer by a PVD method, a Chemical Vapor Deposition (CVD) method, or an Atomic Layer Deposition (ALD) method. In the case of the PVD method, the material to be applied is sputtered in a plasma. The sputtered material then deposits on a substrate on which the layer is intended to be applied. The CVD method is a deposition method from the vapor phase. By the ALD method, layers can be grown atomic layer by atomic layer.

The barrier layer is, for example, deposited by a CVD method or a PVD method. The deposition of the barrier layer may, for instance, be effected in the same installation as the deposition of the contact layer. If the deposition method is a CVD method, for example, then in order to apply the contact layer, first a gas composition for the deposition of the contact layer is admitted into the process chamber. In this case, the contact layer is deposited with exclusion of nitrogen because the polysilicon is intended to be covered with the metal of the contact layer in order to avoid an interaction between nitrogen and silicon. After the contact layer has been applied, the nitrogen-containing gas for the deposition of the barrier layer is admitted into the process chamber. Thus, both contact layer and barrier layer can be applied without vacuum interruption in one and the same installation.

The gate metal layer is deposited onto the barrier layer, for example, by a PVD method or a CVD method.

A gate structure of a transistor includes a gate electrode layer stack with a doped polysilicon layer arranged on a gate dielectric layer, a gate metal layer arranged above the polysilicon layer, and a barrier layer arranged between the polysilicon layer and the gate metal layer. The barrier layer is made of a metal nitride. The barrier layer prevents an interaction, which adversely influences a contact resistance between the polysilicon layer and the gate metal layer, i.e., between the silicon of the polysilicon layer and the metal of the gate metal layer. According to the invention, a contact layer of metal, which avoids an interaction between the nitrogen in the barrier layer and the silicon in the polysilicon layer, is applied between the polysilicon layer and the barrier layer.

Completely covering the polysilicon layer with the contact layer effectively prevents silicon nitride, which increases the contact resistance, from arising during processing. The contact layer according to the invention produces a low-value contact resistance between the gate metal layer and the polysilicon layer compared to a conventional gate structure. A low contact resistance enables switching times to be shortened. In the case of transistors in memory cells, faster access to memory cell contents is then possible.

The barrier layer is, for example, provided on the contact layer as a chemically, thermally, and mechanically stable layer. Nitriding of the polysilicon layer is relatively more effectively prevented if the barrier layer, which includes a metal nitride, has fixedly bound the nitrogen. The nitrogen should remain bound to the metal in the barrier layer even at high temperatures above 800° C. to prevent diffusion of nitrogen into the polysilicon layer.

If the contact layer is titanium and the barrier layer is titanium nitride, the titanium nitride forms a chemically, thermally, and mechanically stable barrier layer.

The contact layer has, for example, a thickness in the range of 1 to 5 nm.

Tungsten is the material for the gate metal layer. The gate metal layer may have a layer sequence including tungsten nitride and tungsten.

### BRIEF DESCRIPTION OF THE DRAWINGS

The invention is explained in more detail below with reference to the FIGS. in which:

FIGS. 1A and 1B show longitudinal sections through gate structures in accordance with the prior art;

FIGS. 2A and 2B show measurement curves for describing the occurrence of tungsten and nitrogen in a conventional gate electrode layer stack;

FIG. 3 shows an electronic microscope micrograph of a conventional gate electrode layer stack; and

FIG. 4 shows a longitudinal section through a gate structure in accordance with an exemplary embodiment of the invention.

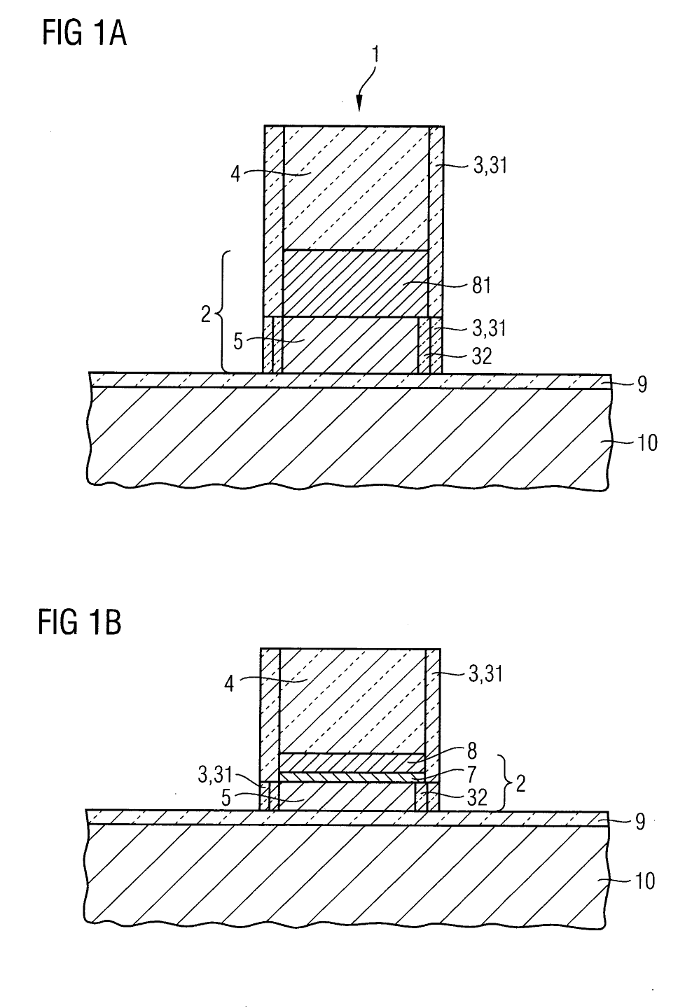

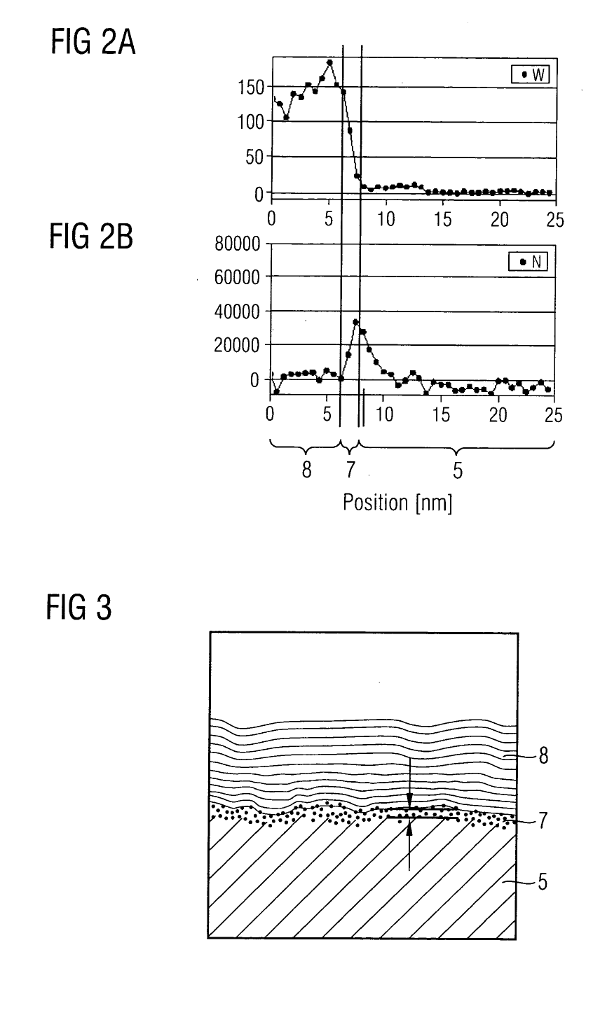

### DETAILED DESCRIPTION

To fabricate a gate structure I according to the invention, a gate electrode layer stack 2 is patterned on a dielectric layer 9 provided on a semiconductor substrate 10. The gate electrode layer stack 2 includes a doped polysilicon layer 5 arranged on the gate dielectric layer 9. A contact layer 6 is provided on the polysilicon layer 5 and a barrier layer 7 is provided on the contact layer 6. The contact layer 6 includes titanium and the barrier layer 7 includes titanium nitride. The gate metal layer 8 is applied to the barrier layer 7. In this example, the gate metal layer 8 includes tungsten. An insulating cap 4 is provided on the gate metal layer 8. Insulating layers 3 are situated on the sidewalls of the gate electrode layer stack 2 and the insulating cap. The insulating layers can include a spacer nitride 31 and a sidewall oxide 32.

The contact layer 6 covers the polysilicon layer 5 and thus prevents interaction between nitrogen contained in the barrier layer 7 and silicon of the polysilicon layer 5. This prevents formation of silicon nitride, which increases contact resistance between the gate metal layer 8 and the polysilicon layer 5. The contact layer 6 may be applied by a PVD method, a CVD method, or an ALD method. During application of the contact layer 6, in the case of a CVD or PVD deposition, for example, the contact layer 6 is applied excluding nitrogen. The barrier layer 7 can then be deposited after application of the contact layer 6 in situ, i.e., in the same installation that the contact layer 6 was also deposited.

In the barrier layer 7, which, according to the invention, includes titanium nitride instead of tungsten nitride, the nitrogen binds relatively more fixedly in the titanium nitride than in the tungsten nitride. No decomposition of the titanium nitride takes place, even during thermal steps at the high temperatures used during the processing of the transistor. Both the contact layer made of titanium and the barrier layer made of titanium nitride, in which the nitrogen is fixedly bound, prevent interaction of nitrogen with the silicon in the polysilicon layer 5. Penetration of metal from the gate metal layer 8 into the polysilicon 5 is prevented by the barrier layer 7. Silicon nitride and metal silicide, both of which impair the contact resistance, are effectively prevented from arising by the construction of the gate structure 1 according to the invention. The contact layer 6 and barrier layer 7 according to the invention make it possible to realize a low-resistance contact between the gate metal layer 8 and the polysilicon layer 5.

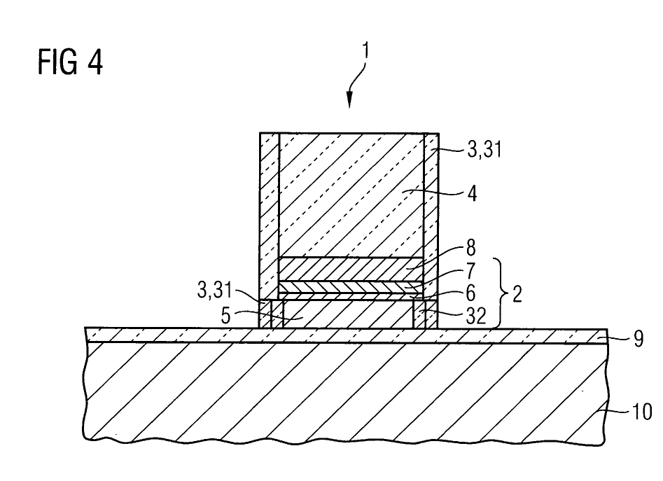

FIG. 4 illustrates the gate structure 1 with the gate electrode layer stack 2 situated on the gate dielectric layer 9 arranged on the semiconductor substrate 10. The gate electrode layer stack 2 includes the polysilicon layer 5, the contact layer 6, the barrier layer 7, and the gate metal layer 8. The insulating cap 4 is provided on the gate metal layer. Insulating layers 3 surrounding the sidewalls are also illustrated. The insulating layers 3 include a spacer nitride layer 31 and a sidewall oxide layer 32.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SYMBOLS

1 Gate structure

2 Gate Electrode layer stack

3 Insulating layer

31 Spacer nitride layer

32 Sidewall oxide layer

4 Insulating cap

5 Polysilicon layer

6 Contact layer

7 Barrier layer

8 Gate metal layer

81 Gate metal silicide layer

9 Gate dielectric layer

10 Semiconductor substrate

1. A method for fabricating a gate structure of a transistor formed in a semiconductor substrate, comprising:
patterning a gate electrode layer stack;
applying a polysilicon layer on a gate dielectric layer provided on the semiconductor substrate to form the gate electrode layer stack;
providing a barrier layer made of a metal nitride;
applying a gate metal layer to the barrier layer, the barrier layer preventing interaction between the silicon in the polysilicon layer and the metal of the gate metal layer which increases the contact resistance between the polysilicon layer and the gate metal layer; and
providing a contact layer between the polysilicon layer and the barrier layer, the contact layer being made of a metal for avoiding interaction between the nitrogen in the barrier layer and the silicon in the polysilicon layer.

2. The method as claimed in claim 1, wherein the barrier layer is provided as a chemically, thermally, and mechanically stable layer on the contact layer.

3. The method as claimed in claim 1, wherein the contact layer comprises titanium and the barrier layer comprises titanium.

4. The method as claimed in claim 3, wherein, the contact layer has a thickness in the range of 1 to 5 nanometers.

5. The method as claimed in claim 1, wherein the gate metal layer is formed of tungsten.

6. The method as claimed in claim 1, wherein the gate metal layer has a layer sequence comprising tungsten nitride and tungsten.

7. The method as claimed in claim 1, wherein the contact layer is applied to the polysilicon layer by a Physical Vapor Deposition (PVD) method, a Chemical Vapor Deposition (CVD) method, or an Atomic Layer Deposition (ALD) method.

8. The method as claimed in claim 1, wherein the barrier layer is deposited by a CVD method or a PVD method.

9. The method as claimed in claim 1, wherein the gate metal layer is deposited onto the barrier layer by a PVD method or a CVD method.

10. A gate structure of a transistor, comprising:
a gate electrode layer stack with a doped polysilicon layer;
a gate metal layer arranged above the polysilicon layer;
a barrier layer arranged between the polysilicon layer and the gate metal layer, the barrier layer being made of a metal nitride for preventing interaction between the silicon in the polysilicon layer and the metal of the gate metal layer, which increases a contact resistance between the polysilicon layer and the gate metal layer; and
a contact layer applied on the polysilicon layer, the contact layer being made of metal for suppressing interaction between the nitrogen in the barrier layer and the silicon in the polysilicon layer.

11. The gate structure as claimed in claim 10, wherein the barrier layer is provided as a chemically, thermally, and mechanically stable layer on the contact layer.

12. The gate structure as claimed in claim 10, wherein the contact layer comprises titanium and the barrier layer comprises titanium nitride.

13. The gate structure as claimed in claim 12, wherein the contact layer has a thickness in the range of 1 to 5 nanometers.

14. The gate structure as claimed in claim 10, wherein the gate metal layer comprises tungsten.

15. The gate structure as claimed in claim 10, wherein the gate metal layer has a layer sequence comprising tungsten nitride and tungsten.

16. A method for fabricating a gate structure of a transistor formed in a semiconductor substrate, in which a gate electrode layer stack is patterned, comprising:
applying a polysilicon layer on a gate dielectric layer provided on the semiconductor substrate to form the gate electrode layer stack;
applying a contact layer made of a metal on the polysilicon layer;
applying a barrier layer made of a metal nitride on the contact layer; and
applying a gate metal layer on the barrier layer, the barrier layer preventing interaction between the silicon in the polysilicon layer and the metal of the gate metal layer, which increases a contact resistance between the polysilicon layer and the gate metal layer,
wherein in order to avoid interaction between the nitrogen in the barrier layer and the silicon in the polysilicon layer, the contact layer comprises titanium, the titanium being deposited with exclusion of nitrogen with a layer thickness in the range of 1 to 5 nanometers.

17. A gate structure of a transistor, comprising:
a gate electrode layer stack with a doped polysilicon layer;
a contact layer provided on the polysilicon layer;
a gate metal layer arranged above the polysilicon layer; and
a barrier layer arranged between the contact layer and the gate metal layer, the barrier layer being made of a metal nitride for preventing interaction between the silicon in the polysilicon layer and the metal of the gate metal layer, which increases a contact resistance between the polysilicon layer and the gate metal layer,
wherein in order to suppress interaction between the nitrogen in the barrier layer and the silicon in the polysilicon layer, the contact layer of titanium is deposited with a layer thickness in the range of 1 to 5 nanometers.
